(19) United States
(12) Patent Application Publication
(10) Pub. No.: US 2022/0209320 A1
(43) Pub. Date: Jun. 30, 2022

(54) LIFE-EXTENDING RECHARGE CONTROL FOR COLD WEATHER LITHIUM-ION POWER SUPPLIES

(71) Applicant: EControls, LLC, San Antonio, TX (US)

(72) Inventors: Kennon H. Guglielmo, San Antonio, TX (US); Jason S. Souder, San Antonio, TX (US); Brent C. Ludwig, San Antonio, TX (US); Matthew J. Martin, San Antonio, TX (US); Justin H. Sanders, San Antonio, TX (US)

(73) Assignee: EControls, LLC, San Antonio, TX (US)

(21) Appl. No.: 17/646,740

(22) Filed: Jan. 3, 2022

Related U.S. Application Data
(60) Provisional application No. 63/132,985, filed on Dec. 31, 2020.

(51) Int. Cl. H01M 10/44; H01M 16/00; H01M 10/0525; H01M 6/50; H01M 10/42; H01M 10/48; H01M 10/615; H01M 10/625; H01M 10/63; H01M 10/657; H02J 7/00; H02J 7/14; H05K 1/18

(52) U.S. Cl. CPC H01M 10/443; H05K 2201/10037; H01M 10/0525; H01M 6/5033; H01M 10/425; H01M 10/441; H01M 10/482; H01M 10/486; H01M 10/615; H01M 10/625; H01M 10/63; H01M 10/657; H02J 7/007194; H02J 7/0013; H02J 7/1423; H05K 1/18; H01M 2220/20; H01M 2010/4271; H05K 2201/10151; H01M 16/00

(57) ABSTRACT

A lithium-ion battery assembly configured to provide electric power to a vehicle. The battery assembly includes a plurality of battery cells interconnected to provide a combined electrical potential between positive and negative terminals of the battery assembly, and a printed circuit board assembly (PCBA) disposed adjacent to a first array of battery cells of the plurality of battery cells. The PCBA includes a collector plate electrically coupled with the first array of battery cells, a temperature sensor configured to obtain temperature readings, a plurality of heaters configured to generate heat using electrical power, and an assembly processor. The assembly processor is configured to obtain readings from the temperature sensor, determine an estimated battery cell temperature, and initiate a heating program by delivering electrical power to the plurality of heaters from an electrical power source when the estimated battery cell temperature is below a threshold.

### CROSS-REFERENCE TO RELATED APPLICATION

This application claims the benefit of the filing date of U.S. Provisional Application Ser. No. 63/132,985, filed on Dec. 31, 2020, entitled “LIFE-EXTENDING RECHARGE CONTROL FOR COLD WEATHER LITHIUM-ION POWER SUPPLIES”, as well as the entire disclosure of which is hereby incorporated by reference into the present disclosure.

### FIELD OF THE INVENTION

The present invention principally relates to recharge controllers for electric batteries of power supplies used in Class I forklifts or in auxiliary electric power supplies for commercial trucks, particularly for lithium iron phosphate (LiFePO4, or “LFP”) batteries used in such applications.

### BACKGROUND OF THE INVENTION

Increasing availability of rechargeable lithium-ion batteries since the 1970's has brought about numerous transformations in electric power supplies. It has nevertheless long been problematic that the capacity of rechargeable batteries diminishes over time, due to a wide variety of factors, including the temperatures in which they operate. It has long been known, for instance, that lithium-ion batteries are susceptible to material damage in the form of reduced capacity when they are recharged at freezing or near-freezing temperatures (i.e., at less than around zero degrees Celsius).

Despite such well-known limitations, rechargeable lithium-ion batteries are known for use in Class I forklifts and in auxiliary power units (APU's) to operate vehicle mounted HVAC systems and other electric systems of the vehicle (the “Pertinent Applications”). Yet, the problems with cold recharge remain, while battery systems for the Pertinent Application are often subject to recharge in freezing temperature, and resulting capacity damage is routinely accepted as part of life.

Therefore, despite the well-known characteristics and long availability of rechargeable lithium-ion batteries, such as those using LFP chemistry, there are still substantial and long-felt unresolved needs for the implementation of improved rechargeable controls for extending the life of such battery technology in the pertinent industries. For an even better understanding of some of the foundational concepts associated with the presently disclosed embodiments, the drawings and descriptions of commonly owned U.S. patent application Ser. No. 16/193,071, entitled “Modular Lithium-Ion Battery System for Forklifts,” filed on Nov. 16, 2018, is incorporated herein by reference in its entirety.

As a result, and for many other reasons, there is a need for a LiFePO₄ recharge controller that helps reduce damage to the batteries and thereby extends the useful life of the batteries used in Class I forklifts and in auxiliary electric power supplies for cabin temperature controls of commercial trucks.

### SUMMARY OF THE INVENTION

The innovations of preferred embodiments improve operations of battery recharge systems and extend the life of lithium-ion systems in applications exposed to cold weather, particularly for the Focused Applications of this inventions, namely for Class I forklifts and for electric auxiliary power units (APUs). Operations are improved in part, by enabling vehicle-mounted secondary heating ventilation and air conditioning (HVAC) systems in commercial trucks, and other vehicles, particularly industrial forklifts.

Further, the lithium-ion battery cells incorporated into the presently disclosed embodiments charge more efficiently, degrade at a much slower rate, and they further maintain greater charge capacity for significantly longer than conventional rechargeable batteries. It is contemplated that the battery modules in the disclosed assemblies are recharged by conventional means, such as the commercial truck's alternator during operation of the engine. However, the controller for such batteries first heats the batteries before charging the batteries of the disclosed embodiments.

Alternatively, preferred embodiments are capable of being charged by truck stop electrification, using an external power supply sourcing power from the grid when available, to recharge the batteries and/or simultaneously to run the electric APU. Presently preferred embodiments of the present invention's exterior dimensions are consistent with a double length Group 31 form factor and consists of one positive and one negative cell array each with two banks of cells, for a total of four banks in the battery module assembly. Each bank of cells contains 72 individual lithium-ion battery cells connected in parallel in preferred embodiments. Within each module, individual battery cells are connected using an approach that is comparable to the Tesla method of wire bonded battery manufacture. An important difference from Tesla, however, involves the use of LFP battery technologies rather than NCA or other LCO battery technologies, as previously discussed. Individual battery cells are wire bonded to collector plate printed circuit board assemblies (PCBA) in each cell array. An APU system will include two of the preferred embodiment modules and would typically include four Group 31 lead acid batteries.

Disclosed embodiments of the positive and negative cell array are similarly assembled in a manner that allows components such as the positive and negative bus terminals to protrude from the plastic lid of the battery module assembly. The positive cell array contains a collector plate printed circuit board PCBA that has an integrated battery management system (BMS) that monitors and/or actively manages battery cell characteristics such as temperature, voltage, and current for the entire system. Located between the battery cells and the collector plates PCBA are plastic battery trays and a structural adhesive. A structural adhesive is used between the top plastic battery tray and the collector plate PCBA. Additionally, the same (or similar) adhesive is used between the battery cells and the top and bottom plastic battery trays.

In order to prevent damage to the lithium-ion battery cells during recharging when the temperature of the lithium-ion battery cells is below a set threshold, a system and method for heating the lithium-ion battery cells are described herein. Additional features for achieving this include a plurality of resistive heating devices, mounted on each collector plate PCBA, such that one or more resistive heating devices are positioned in close proximity to each of the lithium-ion battery cells. Furthermore, also mounted on each collector plate PCBA is a plurality of temperature sensors for continuously or intermittently measuring the temperature of the lithium-ion battery cells. If the sensed temperature of the lithium-ion battery cells is below a threshold temperature, power is routed to the resistive heating devices to generate heat to increase the temperature of the lithium-ion battery cells above the threshold temperature before the recharge cycle begins. Once the temperature of the lithium-ion battery cells is above the threshold temperature, power is then routed to the lithium-ion battery cells for recharging.

### BRIEF DESCRIPTION OF THE DRAWINGS

FIG. 1 illustrates a perspective view of a preferred embodiment of a battery module assembly according to an embodiment of this disclosure.

FIG. 2A illustrates a side view of a semi-trailer truck incorporating the battery module assembly of FIG. 1.

FIG. 2B illustrates a schematic of an alternator of the semitruck trailer of FIG. 2 with the battery module assembly of FIG. 1.

FIG. 3 illustrates an exploded view of the battery module assembly of FIG. 1.

FIG. 4 illustrates a perspective view of a negative cell array of the battery model of FIG. 1.

FIG. 5 illustrates an exploded view of the negative cell array of FIG. 4.

FIG. 6 illustrates a perspective view a positive cell array of the battery module of FIG. 1.

FIG. 7 illustrates an exploded view of the positive cell array of FIG. 6.

FIG. 8A illustrates a top view of a printed circuit board assembly (PCBA) of the battery module assembly of FIG. 1.

FIG. 8B illustrates a bottom view of the PCBA of FIG. 8A.

FIG. 9 illustrates a cutaway view of a battery cell disposed in the battery module assembly of FIG. 1.

FIG. 10 is a flowchart illustrating a method of heating and charging battery cells of a battery module assembly, according to an embodiment of this disclosure.

FIG. 11 illustrates a simplified graphical representation comparing sample discharge curves over time of a typical lead-acid battery and a disclosed LFP battery module.

FIG. 12 illustrates a simplified graphical representation comparing sample charge curves over time of a typical lead-acid battery and a disclosed LFP battery module assembly.

FIG. 13 illustrates a simplified graphical representation comparing sample charge curves over time of a lithium nickel manganese cobalt oxide (NMC) battery and the disclosed LFP battery cell.

### DETAILED DESCRIPTION OF PREFERRED EMBODIMENTS

The following descriptions relate to presently preferred embodiments and are not to be construed as describing limits to the invention, whereas the broader scope of the invention should instead be considered with reference to the claims, which may be now appended or may later be added or amended in this or related applications. Unless indicated otherwise, it is to be understood that terms used in these descriptions generally have the same meanings as those that would be understood by persons of ordinary skill in the art. It should also be understood that terms used are generally intended to have the ordinary meanings that would be understood within the context of the related art, and they generally should not be restricted to formal or ideal definitions, conceptually encompassing equivalents, unless and only to the extent that a particular context clearly requires otherwise.

For purposes of these descriptions, a few wording simplifications should also be understood as universal, except to the extent otherwise clarified in a particular context either in the specification or in particular claims. The use of the term “or” should be understood as referring to alternatives, although it is generally used to mean “and/or” unless explicitly indicated to refer to alternatives only, or unless the alternatives are inherently mutually exclusive. When referencing values, the term “about” may be used to indicate an approximate value, generally one that could be read as being that value plus or minus half of the value. “A” or “an” and the like may mean one or more, unless clearly indicated otherwise. Such “one or more” meanings are most especially intended when references are made in conjunction with open-ended words such as “having,” “comprising” or “including.” Likewise, “another” object may mean at least a second object or more.

### Preferred Embodiments

The following descriptions relate principally to preferred embodiments while a few alternative embodiments may also be referenced on occasion, although it should be understood that many other alternative embodiments would also fall within the scope of the invention. It should be appreciated by those of ordinary skill in the art that the techniques disclosed in these examples are thought to represent techniques that function well in the practice of various embodiments, and thus can be considered to constitute preferred modes for their practice. However, in light of the present disclosure, those of ordinary skill in the art should also appreciate that many changes can be made relative to the disclosed embodiments while still obtaining a comparable function or result without departing from the spirit and scope of the invention.

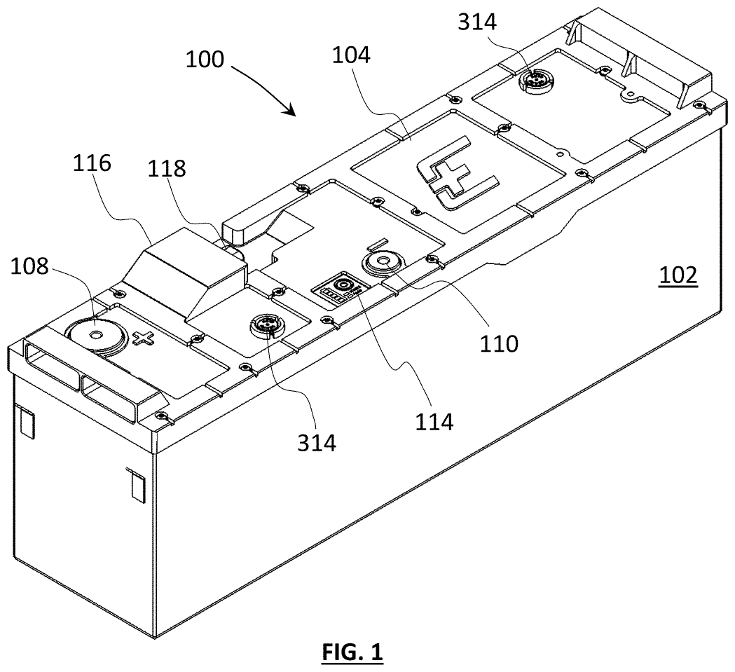

With reference to FIG. 1, there is shown a preferred embodiment of the lithium iron phosphate (LFP) battery module assembly 100. The exterior dimensions of battery module assembly 100 are consistent with a double length Group 31 form factor, although it should be understood by those of ordinary skill in the art that the disclosed features, as well as the advantages derived therefrom, could be incorporated into other battery module form factors while still providing all or most of the advantages of the battery module assemblies herein described. Note that being “consistent” with a form factor allows for flexibility in actual size. It is also anticipated that certain aspects of embodiments may be in other form factors as custom applications require.

Visible in FIG. 1 are the aluminum enclosure base 102 and the plastic lid 104. Preferred embodiments include openings for ports in the plastic lid 104 for input and output. The positive bus terminal 108 and negative bus terminal 110 are accessible through the plastic lid 104. Lid 104 has two vent patches 314 configured to vent module 100 assembly 100 while also keeping dust and water from entering module 100. A touch pad HMI 114 is also visible and protruding from the plastic lid 104. Lid 104 includes an electrical connector bulkhead 116 that houses an electrical connector receptacle 118, which, in some embodiments, is 6-pin flange receptacle. It will be evident to those skilled in the art that an alternative number or type of ports could be present while still being within the scope of the disclosed embodiments.

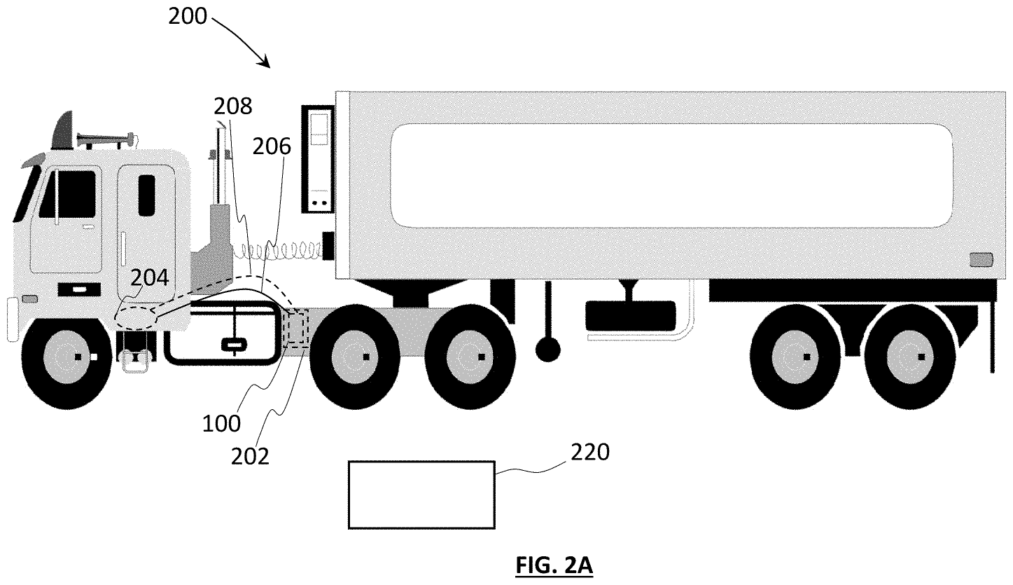

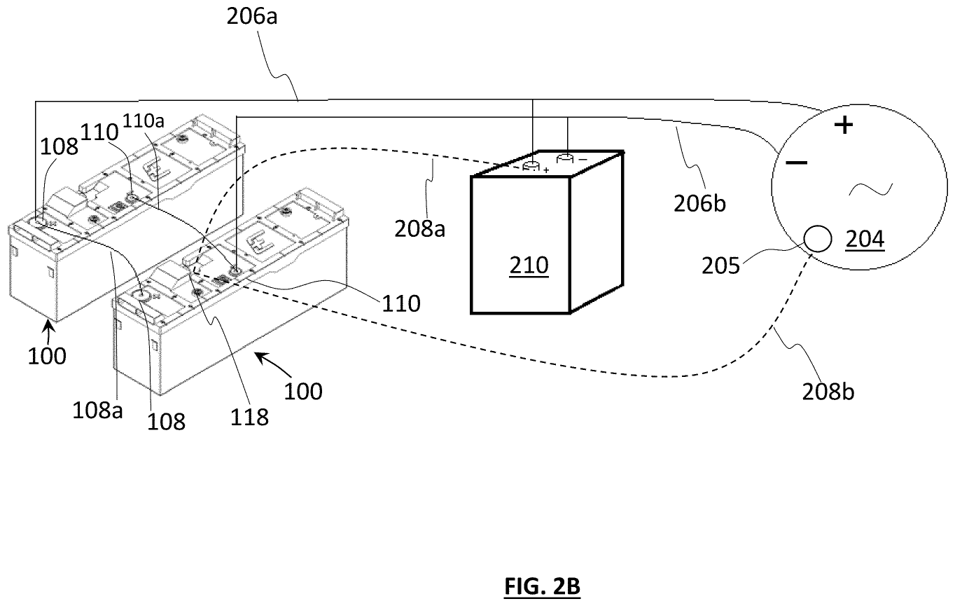

FIG. 2A illustrates a side view of a semi-trailer truck 200 onto which the disclosed battery module assembly 100 may be mounted. The battery module assembly 100 is contained in a compartment or housing 202 (illustrated here as a rectangle) attached to the frame of semi-trailer truck 200 behind the cab and provides power to various truck functions, such as the vehicle-mounted heating ventilation and air conditioning (HVAC), the battery module assembly 100 particularly being operative when the main drive engine of semi-trailer truck 200 is not running. Accordingly, the module assembly 100 can be considered an auxiliary power unit (APU) of the semi-trailer truck. The module assembly 100 and housing 202 are depicted in FIG. 2A using dashed lines to illustrate their position between frame rails of the frame of the truck 200. However, in other embodiments, the module assembly 100 and associated housing are disposed in other positions on truck 200, such as on top of the frame rails or the outside of the frame rails.

The alternator 204 (illustrated as a dashed-line oval) of semi-trailer truck 200 connects to battery module assembly 100 with charge cables 206 and remote sense wire 208. The alternator 204 charges battery module assembly 100 when the main drive engine is running. Alternator 204 operates as a constant voltage source and must be appropriately sized in order to adequately charge battery module assembly 100. Additionally, preferred embodiments of battery module assembly 100 are capable of being charged by truck stop electrification, using an external power supply sourcing power from the grid when available, to recharge and/or simultaneously to operate the battery module assembly 100.

Due to limited alternator capability and limited charge time, lead-acid banks typically consist of up to 4 ground 31 lead-acid batteries in parallel. Although different APUs may operate at various values, a new lead-acid battery bank, while operating at 50-55 A with some on/off cycling, typically achieves a maximum of about 6-8 hours of run-time. In contrast, while operating at the same 50-55 A with the same on/off cycling, battery module assembly 100 can achieve a run-time of up to 13 hours, or more, before requiring recharging. Due to its LFP chemistry, battery module assembly 100 can safely discharge 90% of its capacity in a discharge cycle. In contrast, lead-acid batteries can only discharge 80% before permanent damage occurs to the overall capacity.

While common lead-acid batteries have an average life of 300 to 500 cycles with 20% degradation of stored charge, battery module assembly 100 can last over 2000 to 3000 cycles, or up to six times as many, with the same 20% or possibly less, such as 10%, degradation of stored charge. Since operating times are reduced over the period of numerous charge and discharge cycles, battery module assembly 100 can operate roughly twice the duration of conventional lead-acid APUs. Those skilled in the art will recognize that the image shown in FIG. 2A is for illustrative purposes, and the disclosed embodiments can be incorporated into a semi-trailer truck 200 by other means, achieving the same results. Additionally, it should be noted that the values presented are not intended to be limiting and are for illustrative purposes.

It is contemplated that the alternator 204 is capable of remote voltage sensing of the starting battery voltage, and battery module assembly 100 will be capable of actively controlling this remote sense input to reduce charge time and improve the life cycle of the battery module assembly 100. Conventional charging methods often result in a lower voltage at the battery than the voltage being sent by the alternator 204. Various factors may cause the voltage seen at the battery module assembly 100 to be significantly lower than the voltage at the terminals of the alternator 204. Voltage drop is affected by wire length, wire gauge, aging or corroded cables, loose cables, cables that are improperly connected, and the overall charging path topology, among other factors. An opportunity to increase the voltage seen at the battery module assembly 100 is detected by sensing charge current and starting battery voltage at the remote sense wire 208. If an opportunity to safely increase the alternator's 204 output voltage is detected, battery module assembly 100 can add or subtract small voltage offsets in the alternator's 204 remote sense input 205, which can cause the alternator 204 to increase voltage output to compensate for the voltage drop, ensuring an optimal operating voltage and current being received at the battery module assembly 100. Those skilled in the art will recognize that additional voltage injected into the alternator's remote sense circuit forces higher charge current into the battery module assembly 100, achieving a full state of charge faster. Additional voltage being sent by the alternator 204 in this method can result in a full charge in about half the time of conventional charging methods. Other advantages, such as limiting current initially to decrease required alternator size or limiting voltage to protect from an alternator that is regulating too high, can also be seen.

Additionally, battery module 100 can be electrically coupled with an external power source 220 to recharge the battery cells 506 of battery module 100. For example, power source 220 can be electrically coupled with terminals 108, 110 of battery module assembly 100 to charge battery cells 506 of battery module assembly 100. In some embodiments, external power source 220 is a charging station for rechargeable battery module assembly 100.

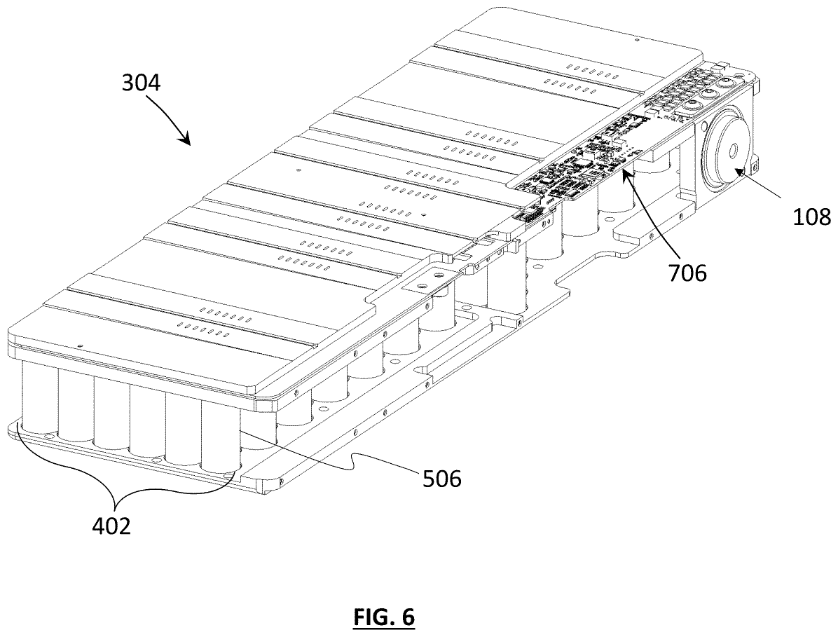

FIG. 2B, there is shown a more detailed view of the alternator 204 and battery module assembly 100. Specifically, FIG. 2B illustrates a configuration in which two battery assembly modules 100 are coupled together with alternator 204. One with skill in the art will understand how FIG. 2B can be applied to configurations in which more or less than two battery module assemblies 100 are used. The alternator 204 and battery module assemblies 100 are connected by charge cables 206a, 206b and remote sense wires 208a, 208b. In addition to charging the truck starting battery 210, the charge cables 206a & 206b connect to the battery module assembly 100 allowing the alternator 204 to charge the battery module assembly 100 between use. One charge cable 206a connects to the positive bus terminal 108 and one charge cable 206b connects to negative bus terminal 110. Connecting wire 108a electrically couples the positive terminals 108 of the two battery modules 100 together, and connecting wire 110a electrically couples the negative terminals 110 of the two battery modules 100 together. The remote sense wire 208a connects a positive terminal of a starting battery 210 of truck 200 directly to one of the battery module assemblies 100 at the 6-pin flange receptacle 118, and remote sense wire 208b connects the same battery assembly 100 at the 6-pin flange receptacle 118 to a remote sense terminal 205 of alternator 204. An input 208a and output 208b occupy two of the pins in the 6-pin flange receptacle 118, which connects to the BMS 706 (shown in detail in FIGS. 6-8A). One with skill in the art will understand that BMS 706 is one or multiple processors, controllers, and/or computers configured to monitor and/or actively manage battery cells 506 characteristics such as temperature, voltage, and current for the entire system The BMS 706 measures the voltage of the vehicle's electrical system, where remote sense wire 208 is normally located, and delivers an offset voltage to the remote sense terminal 205. The alternator 204 then increases the voltage output to compensate for the artificial voltage drop, thereby increasing the charge current to the battery module assemblies 100. In addition to increasing alternator voltage to increase charging current to battery module assembly 100, the BMS 706 also limits the magnitude of the applied negative offset so as to not violate the voltage or current limits of the alternator, the voltage limits of the starting battery 210, the voltage or current limits of the vehicle's electrical systems, or the voltage limits of battery module assembly 100. It will be evident to those skilled in the art that the drawing is not to scale and is only for illustrative purposes detailing how the components are connected.

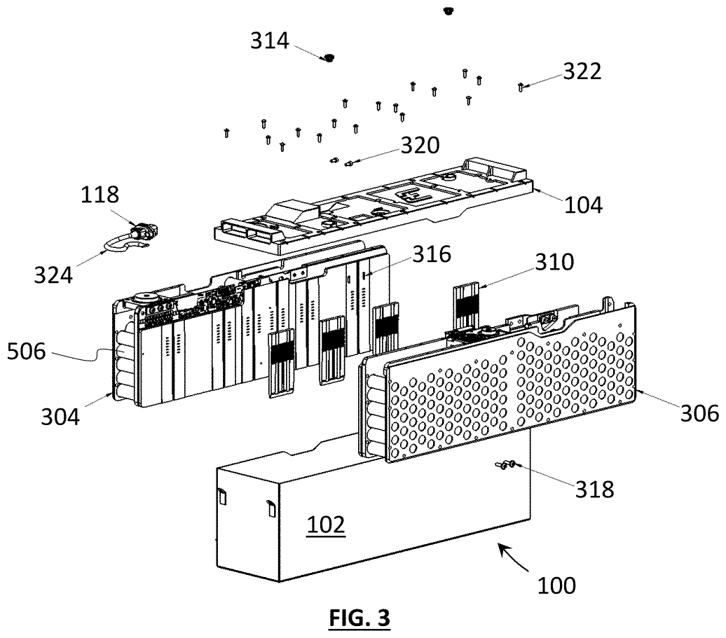

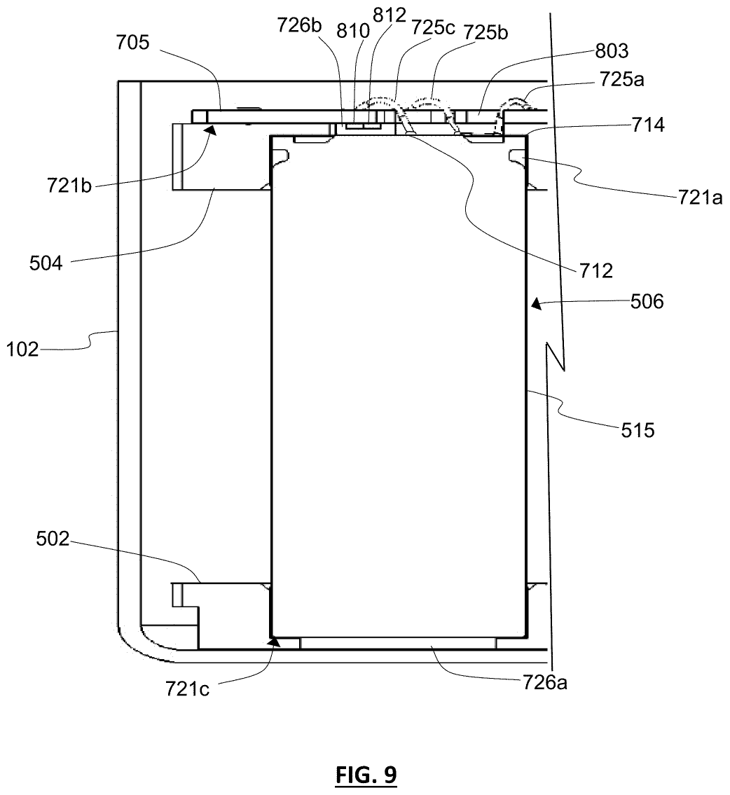

FIG. 3 illustrates an exploded view of the battery module assembly 100. The battery module assembly 100 contains two sub-assemblies or cell arrays, one positive cell array 304, and one negative cell array 306. Cell arrays 304, 306 include a plurality of lithium-ion battery cells 506. Preferably, the battery cells 506 are of the LFP type. Cell arrays 304, 306 are glued into the aluminum enclosure base 102. Multiple self-locking wedges 310 are installed to spread the cell arrays 304 & 306 apart, and to force contact with the aluminum enclosure 102 and an optional thermal gap filler (as seen in FIG. 9). Lid 104 is then glued and screwed down on top of the sub-assemblies 304 & 306 and enclosure base 102.

A variety of screws are used in the assembly process, preferably HSHC, M5X10 SS 320, and Delta PT 322 are used where appropriate to secure the plastic lid 104 in place. Additionally, fasteners 316 and 318 are preferred to be used to secure the sub-assemblies 304 & 306 and the enclosure base 302 and respectively. However, it will be evident to those skilled in the art that several alternative attachment methods can be used to secure individual components in place throughout the battery module 100.

Also visible in FIG. 3, is 6-pin flange receptacle 118 which protrudes through the plastic lid 104 and with an attached flying lead wire harness 324 for connecting to the battery management system (BMS) 706. Additionally, vent plugs 314, preferably TEMISH, are used in the plastic lid 104, to prevent water and dust from entering the battery module assembly 100.

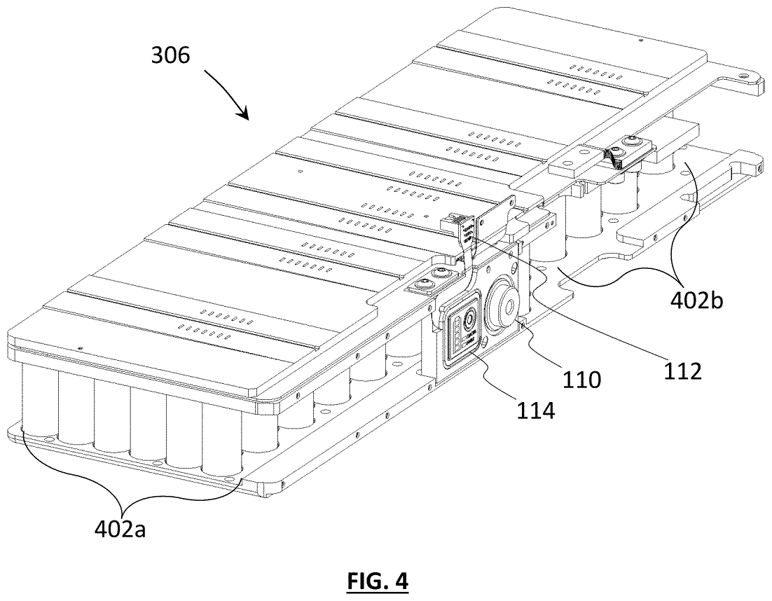

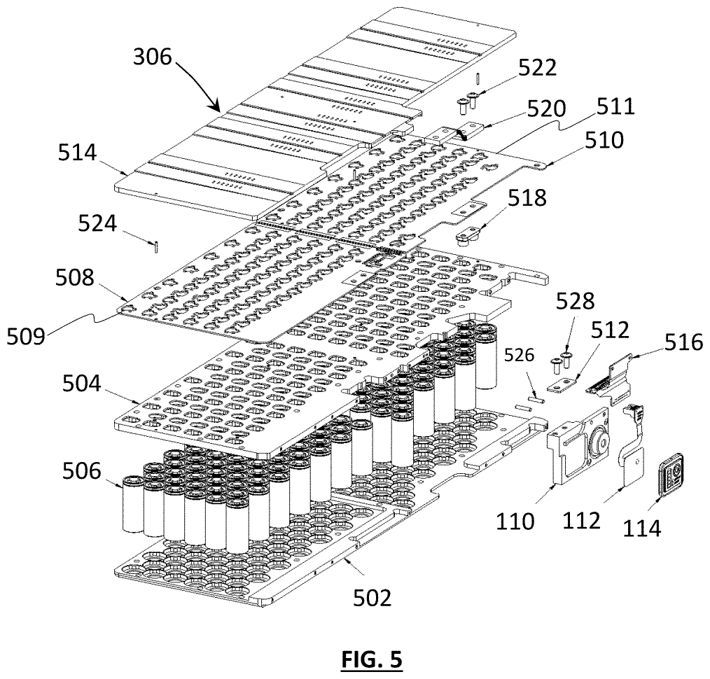

FIG. 4 illustrates a preferred embodiment of sub-assembly or negative cell array 306. Included in each battery module 100 is one negative cell array 306 and one positive cell array 304 (as seen in FIG. 5). Each sub-assembly 304 & 306 contain two banks of cells 402, shown here as 402a & 402b for a total of four in each battery module assembly 100. Also shown is the negative bus terminal 110, a light emitting diode (LED) dome 112, and touch pad 114 all of which protrude from the plastic lid 104 when battery module assembly 100 is fully assembled.

FIG. 5 illustrates an exploded view of a preferred embodiment of negative cell array or sub-assembly 306. Each sub-assembly 304 & 306 contains two banks of cells 402 which are made up of LFP battery cells 506 connected in parallel. Presently, preferred embodiments include 72 cells 506 in each bank 402. The cells 506 are held in place between a cell tray bottom 502 and cell tray top 504. Dowel pins 526 are inserted into the cell tray bottom 502 to aid in securing the lid to the negative cell array 306 when assembled. Each cell 506 is wire bonded to printed circuit board assembly (PCBA) 508, 510. Specifically, PCBA 508 has a collector plate 509 and PCBA 510 has a collector plate 511, and each cell 506 is boned to its corresponding collector plate 509, 511 disposed adjacent to the cell 506. A flex bus 520 is attached and held into place on PCBA 510 with screws 522, and a nut plate 518. A wire guard tray 514 is held in place with dowel pins 524 over the PCBAs 508 & 510. Although, as illustrated, there is shown two separate PCBAs 508, 510 coupled together, one with skill in the art will understand that in some embodiments, PCBAs 508, 510 are combined as a single piece. Additionally, PCBAs 508, 510 can be referred to together as a PCBA for the negative cell array 306.

Preferred embodiments of negative cell array 306 also include negative bus terminal 110, LED dome 112, and touch pad 114. Negative bus terminal 110 fits over a flex circuit 516 and is secured with a washer plate 512 and screws (HSFBHC, M616) 528 when negative cell array 306 is assembled. Those skilled in the art will recognize that several alternative attachment methods can be used with similar results to secure the components in place in the negative cell array 306, and the components described above only represent a preferred method.

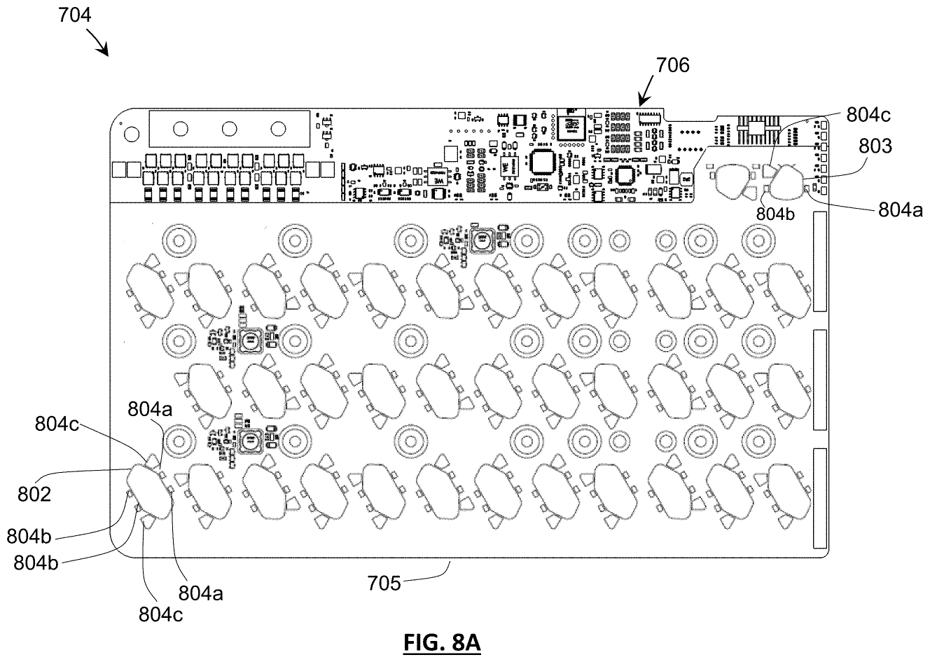

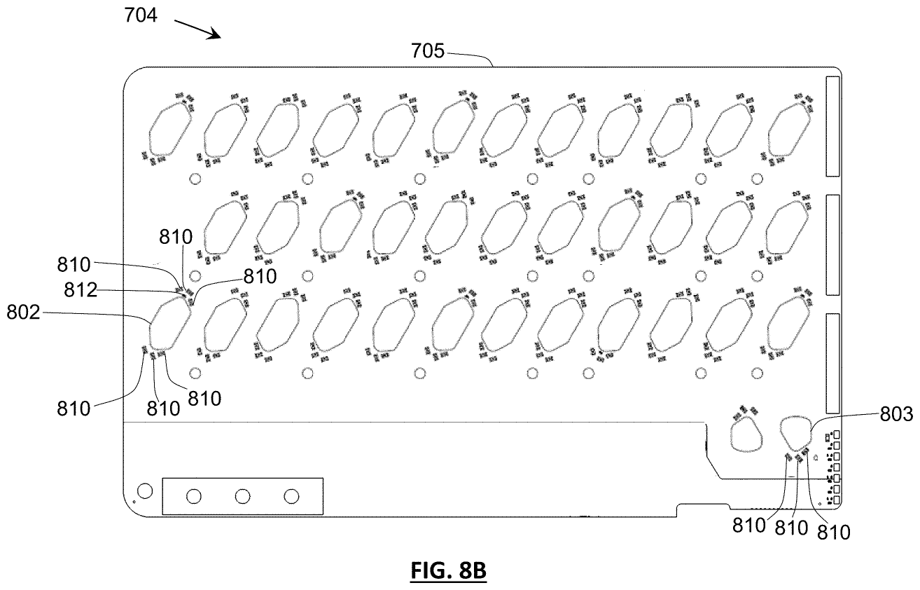

FIG. 6, illustrates a closer view of a preferred embodiment of the positive cell array 304. The positive cell array 304 is assembled similar to the negative cell array 306 and also contains two cell banks 402 consisting of individual cells 506. When assembled, the positive bus terminal 108 from positive cell array 304 protrudes through the plastic lid 104 of battery module array 100. Also visible, is the BMS 706, which, according to some embodiments, is present in the positive cell array 304, and will be discussed further with respect to FIG. 8A.

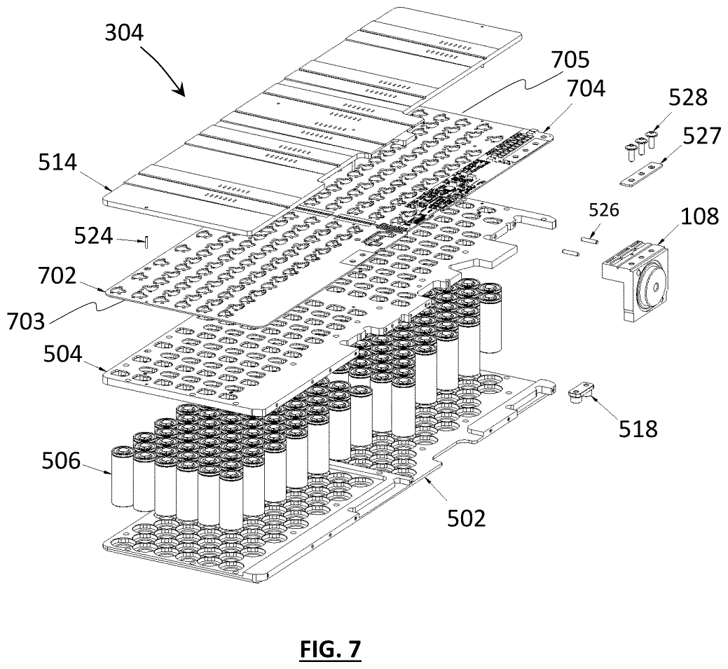

With reference to FIG. 7, there is shown an exploded view of a preferred embodiment of positive cell array or sub-assembly 304. Individual cells 506 are held in place between a cell tray bottom 502 and cell tray top 504. Dowel pins 526 are inserted into the cell tray bottom 502 to aid in securing the positive cell array 304 to the lid when assembled. Each cell 506 is wire bonded to a PCBA 702, 704. Specifically, PCBA 702 has a collector plate 703 and PCBA 704 has a collector plate 705, and each cell 506 is boned to its corresponding collector plate 703, 704 disposed adjacent to the cell 506. A wire guard tray 514 is held in place with dowel pins 524 over the collector plates 702 & 704. Although, as illustrated, there is shown two separate PCBAs 702, 704 coupled together, one with skill in the art will understand that in some embodiments, PCBAs 702, 704 are combined as a single piece. Additionally, PCBAs 702, 704 can be referred to together as a PCBA for the positive cell array 304.

Preferred embodiments of positive cell array 304 also include positive bus terminal 108. Positive bus terminal is secured with screws 528, a nut plate 518, and washer plate 527. Those skilled in the art will recognize that several alternative attachment methods can be used with similar results to secure the components in place in the positive cell array 304, and the components described above only represent a preferred method.

FIG. 8A illustrates a top plan view of PCBA 704. As previously mentioned, PCBA 704 comprises PCB collector plate 705 and a BMS 706. Each battery cell 506 is wire bonded to the PCB 704. There are three wires 725a, 725b, 725c (shown in FIG. 9) bonded to pads 804a, 804b, and 804c, on PCB collector plate 705 for each battery cell 506. Two of the wires 725a, 725b are for the negative terminal of the individual cell 506 and are bonded to negative pads 804a, 804b, and one of the wires 725c is positive for the individual cell and is bonded to positive pad 804c. The purpose of two negative wires is for redundancy.

Collector plate 705 has a plurality of openings 802, 803 through which the battery cells 506, which are adjacent to the bottom side of PCBA 704, can be accessed from the top side of PCBA 704. As illustrated, collector plate 705 comprise large openings 802 and small opening 803. Each large opening 802 is associated with, and provides access to, two of the battery cells 506, while each small opening 803 is associated with, and provides access to, one battery cell 506. The wires 725a, 725b, 725c associated with each battery cell 506 pass through the cell's 506 associated opening 802, 803 and are bonded to collector plate 705 at associated bonding pads 804a, 804b, and 804c. Because large openings 802 are each associated with two battery cells 506, there are two sets of bonding pads 804a-804c associated with each large opening 802. Because small openings 803 are each associated with one battery cell 506, there is one set of bonding pads 804a-804c associated with each small opening 803.

In preferred embodiments, bonding pads 804a-804c comprise electroplated gold, and wires 725a, 725b, 725c are bonded to bonding pads 804a-804c with an aluminum-nickel alloy. In preferred embodiments, enclosure base 102 and lid 104 are sealed together when constructed using an adhesive sealant. The sealing of enclosure base 102 and lid 104 prevents moisture from entering module 100. Without proper sealing, unwanted moisture can enter module 100 and can cause galvanic corrosion to occur between the electroplated gold pads 804a-804d and aluminum bonded wires 725a, 725b, 725c.

FIG. 8B illustrates a bottom side view of PCBA 704, the opposite side of the view shown in FIG. 8A. It has been observed that damage to lithium-ion battery cells 506 may occur when attempting to charge lithium-ion battery cells 506 when the ambient temperature is low, particularly a temperature below 0° C.-5° C. In order to prevent such damage to the lithium-ion battery cells 506 during recharging, particularly when the ambient temperature is low, disclosed embodiments include resistive heating devices 810 mounted on collector plate 705 in close proximity to each lithium-ion battery cell 506. One example of a resistive heating device 810 that may be incorporated in the disclosed embodiments is a 1206 thick film pick and place surface mount resistor, although other suitable resistors may be used. Each battery cell 506 is associated with at least one associated resistive heating device 810. In some embodiments, such as the embodiment illustrated, there can be three heating devices 810 associated with each battery cell 506. As shown in FIG. 8B, there are six resistive heating devices 810 surface mounted to collector plate 705 near each large opening 802, and three heating devices 810 surface mounted to collector plate 705 near each small opening 803. As previously described, each large opening 802 is associated with two battery cells 506, and each small opening 803 is associated one battery cell 506. Accordingly, each battery cell 506 is disposed in proximity of three heating devise 810 of the battery cell's 506 associated opening 802, 803.

Given that the battery module 100 is essentially a closed system, the heat from the resistive heating devices 810 is able to radiate through the battery module system 100 in order to raise the temperature of each lithium-ion battery cell 506 above a set threshold temperature. Preferably, resistive heating devices 810 are positioned close to the top cap of each lithium-ion battery cell 506. As discussed in greater detail below, because an outer casing 515 (as illustrated in FIG. 9) for each battery cell 506 is preferably constructed of metal, and more preferably constructed of nickel plated carbon steel, the case of each lithium-ion battery cell 506 is thermally conductive, and preferably an efficient heat conductor to more quickly raise the temperature of each lithium-ion battery cell 506 prior to recharging.

In addition to the resistive heating devices 810, some embodiments may also utilize a thermally conductive material to decrease the time necessary for heating the lithium-ion battery cells 506 to the set threshold temperature. For example, a small amount of the thermally conductive gap filling material 726b (as shown in FIG. 9) or a thermal adhesive may be placed on and/or under each of the resistive heating devices 810 to help direct heat from resistive heating devices 810 to the battery cells 506. Placing a small amount of the thermally conductive gap filling material 726b in this way further helps to reduce localized heating effects that could interfere with the accurate measurement of the temperature of lithium-ion battery cells 506 by thermistors 812. Other alternatives for directing heat from the resistive heating devices 810 to the lithium-ion battery cells 506 include a thermal grease or a sheet material that is a cured version of the thermally conductive gap filling material 726b for use as described.

To assist with better circulation of the heat generated by resistive heating devices 810, some embodiments may include one or more fans positioned within the interior of battery module 100. Addition of one or more fans creates convection of the heat generated by resistive heating devices 810 to more quickly raise the temperature of each lithium-ion battery cell 506. Preferably, the one or more fans are mounted in the most effective position to circulate the heated air. Each fan is preferably about 40 millimeters (mm) in diameter. However, other size fans are contemplated, including fans that are smaller than 40 mm, as well as larger fans such as those fans that are 60 mm, 80 mm, 120 mm, or even 140 mm in diameter. Use of one or more fans may optimize the air, and thus heat, circulation within the interior of battery module 100 such that fewer resistive heating devices 810 may be required and/or smaller resistive heating devices 810 may be used.

For measuring temperatures near battery cells 506, a plurality of temperature sensors 812 are mounted on collector plate 705. As illustrated, in some embodiments, there can be eight temperature sensors 812 substantially evenly dispersed across the bottom surface of the of collector plate 705. One with skill in the art will understand that in other embodiments there can be more or less than eight temperature sensors 812 disposed on collector plate 705. Although temperatures sensor 812 are referred to as thermistors throughout this specification, one with skill in the art will recognize that other types of temperature sensor can be used other than thermistors. Thermistors 812 are electrically connected with BMS 706 such that BMS 706 and thermistors 812 are together configured to take temperature measurements. Thermistors 812, with BMS 706, take temperature readings inside the battery module 100, such that sensed temperature readings from thermistors 812 are communicated to BMS 706. Thermistors 812 are positioned in proximity to the lithium-ion battery cells 506.

Although FIGS. 8A-8B describe PCB 704, on with skill in the art will recognize that PCBs 702, 508 and 510 are substantially the same as the described PCB 704. In the illustrated embodiment, PCB 704 is the only PCB with a BMS 706. However, PCBs 702, 704, 508, 510 are electrically coupled with one another such that BMS 706 is configured to monitor the state of each of the cell 506 of battery assembly 100. PCBs 702, 704, 508, 510 are electrically coupled with one another such that BMS 706 is configured to, for example: obtain temperature readings from the temperature sensors 812 of each of the PCBs 702, 704, 508, 510; deliver electricity from a power source to the heaters 810 of each of the PCBs 702, 704, 508, 510; and monitor the state of and deliver electricity for charging from a power source to the battery cell 506 of each of the PCB s 702, 704, 508, 510.

FIG. 9 illustrates a cutaway view of a single battery cell 506 in place within module 100. As previously mentioned, battery cells 506 and other components are surrounded by a protective enclosure 320 and cover 321. Above battery cell 506, there is a plastic battery tray 504. Adhesive 721a is used between the top of battery cell 506 and top battery tray 504. Similarly, an adhesive 721b is applied between the top battery tray 504 and collector plate 705. Preferably, each of these adhesives 721a, 721b are structural adhesives. Furthermore, in preferred embodiments, adhesives 721a, 721b are not electrically conductive. Each adhesive 721a, 721b may be a urethane-based adhesive, an acrylic adhesive, or another type of adhesive that provides similar functionality. Adhesive 721c is applied between the bottom of battery cell 506 and bottom battery tray 502. Furthermore, in some embodiments, a thermally conductive gap filling material 726a is used between the bottom of battery cell 506 and enclosure 320. The gap filling material 726a allows heat to be transferred from the battery cells to the enclosure 320 so the heat can be transferred and dissipated from each battery cell 506. As previously mentioned, in preferred embodiments, enclosure 102 is made of aluminum, which thermally conductive material is effective in dissipating heating from battery cells 506 to outside of module 100. One with skill in the art will understand that including gap filling material 726a is optional. In some embodiments of this disclosure, module 100 does not include gap filling material 726a in order to better retain heat generated by heaters 810. In preferred embodiments, gap filling material 726a, 726b is a silicone-based material. Specifically, in preferred embodiments, gap filler material 726a, 726b is CoolTherm® SC-1600 thermally conductive silicone gap filler, which is a two-component thermally conductive silicone system comprising a resin and a hardener, and has a thermal conductivity of value of 3.7 Watts per meter Kelvin. Gap filler material 726a, 726b, and specifically CoolTherm® SC-1600, can be applied to the ends of battery cell 506, as shown in FIG. 9, using an applicator gun or an XY robotic dispenser table and can be cured for 24 hours at room temperature or for 30 minutes and 100° C.

In some embodiments, there is an individual gap filler materiel 726a associated with the bottom end of each of the battery cells 506. Similarly, in some embodiments, there is an individual gap filler material 726b associated with the top end of each of the batter cells 506. However, in some embodiments, an individual gap filler materiel 726a is associated with a plurality of the battery cells 506 such that, for example, in some embodiments a single gap filler material is disposed between enclosure base 102 and each of the associated battery cells 506. In some embodiments, an individual gap filler materiel 726b is associated with a plurality of the battery cells 506 such that, for example, in some embodiments a single gap filler material 726b is disposed between PCB 704 and each of the associated battery cells 506.

As previously described, each battery cell 506 is wire bonded to PCB collector plate 705. FIG. 9 illustrates that positive wire 725c and two negative wires 725a, 725b pass through opening 803 and are wire bonded to the top of PCB collector plate 351b. Positive wire 725c is connected to a positive terminal 712 of battery cell 506. Positive terminal 712 is located at a center portion of the top end of battery cell 506. Negative wires 725a, 725b are connected to a negative terminal 714 of battery cell 506. Negative terminal 714 is located along an outer circumferential raised edge of the top end of battery cell 506. Although FIG. 9 depicts a battery cell 506 associated with PCB collector plate 705 and opening 803, one with skill in the art will understand that each battery cell 506 is assembled with the associated PCB collector plate 509, 511, 703, 705 and opening 802, 803 according to what is disclosed FIG. 9.

In addition to be disposed at the bottom of battery cell 506, and as previously discussed, thermally conductive material 726b is also disposed at a top end of battery cell 506 between battery cell 506 and PCB collector plate 35 lb. Specifically, conductive material 726b is disposed to contact the top of end of battery cell 506 and heaters 810 of PCB collector plate 705. Accordingly, thermally conductive material 726b is configured to transfer heat between PCB collector plate 705 and battery cell 506. Specifically, thermally conductive material 726b is configured to efficiently transfer heat produced by heaters 810 to battery cell 506. Although one heater 810 is shown in the cutaway view of FIG. 9, as previously discussed in FIG. 8B, the preferred embodiment includes three heaters for each battery cell 506. One with skill in the art will understand that the cutaway view is cut in a way that only illustrates one of the three heaters 810 and that thermally conductive material 726b contacts each of the three heaters 810 and transfers heat from each of the three heaters 810 to battery cell 506.

Additionally, as illustrated in FIG. 9, for openings 802, 803, in proximity to thermistors 812, thermally conductive material 726b is disposed between the top of battery cell 506 and thermistor 812. With this arrangement, in addition to its close proximity to battery cell 506, thermistor 812 can obtain a more accurate temperature reading of cell 506 due to its thermal connection with cell 506 via thermally conductive material 726b.

Battery cell 506 has an outer casing 515 comprised of a thermally conductive material. Outer casing 515 is configured to transfer heat between battery cell 506 and gap fillers 726a, 726b. Specifically, outer casing 515 is configured to transfer heat generated by battery cell 506 to the lower gap filler 726a contacting enclosure 320. Accordingly, the thermally conductive properties of casing 515 assist in transferring heat generated by battery cell 506 to an outside of module 100. Further, a top end section of outer casing 515 is contact with upper gap filler 726b and is configured to transfer heat generated by heaters 810 throughout the battery cell 506. Accordingly, as will be discussed in further detail below, in cold weather situations, the thermally conductive properties of casing 515 assist in the transfer of heat from heater 810 to battery cell 506. Additionally, due to casing's 515 thermally conductive properties, thermistor 312 can gather more accurate temperature readings of battery 506. In preferred embodiments, casing 515 comprises a metallic material, such as, for example, nickel plated carbon steel.

Referring back to FIG. 8A, BMS 706 monitors the health of the module 100 to include cell voltage, current, and temperature. The battery cells 506 of module 100 are connected in series and/or parallel via wire bonding and ultimately terminate into integrated BMS 706. The wire bonding is completed using a method similar to the Tesla ultrasonic friction welding method. The openings 802, 803 shown are used to wire bond the battery cells 506 to the PCB 704. Passing through each opening 802, 803 in PCBA 704, wires 725a, 725b, 725c are bonded to both the PCB 704 and the battery cell 506. The PCBA 704 is then used to directly transfer the electric current through the interior of the battery module 100. The use of the wire bonds 725a, 725b, and 725c couple battery cells 506 to collector plate 705 prevent the entire battery module 100 from failing if one battery cell 506 malfunctions because the failed cell will disconnect through fusing action in that cell's wire bond while other cells are still independently connected to the PCBA 704.

Within the battery module assembly 100, a plurality of self-contained battery cells 506, preferably somewhere in the range from one-hundred sixty (160) to four-hundred (400) cells per battery module assembly 100, are connected in a combination of series and parallel using a wire bonding method. Alternate embodiments may contain variations of the arrangement or numbers of battery cells 506. The wire bonding method connects batteries using wire bonds instead of busbars. The wire bonding is achieved through ultrasonic friction welding. By interconnecting batteries with wire bonding, the wire bonds can prevent short circuits while acting as fuses. The wire bonds are made of wire that allows for the expected current to pass through without significant overheating and allows the wire bond to break to prevent over-currents of individual cells. Additionally, current-controlled MOSFETs acting as resettable fuses, or other forms of resettable or conventional fuses, are placed inside battery module assembly 100 in series with battery cells 506. If the current carrying capacity is exceeded, the fuse will open and prevent the overcurrent from also blowing out the wire bonds. Alternative embodiments of this design may connect battery cells 506 in parallel. Additionally, alternative methods of connecting battery cells 506 could include traditional soldering and spot welding.

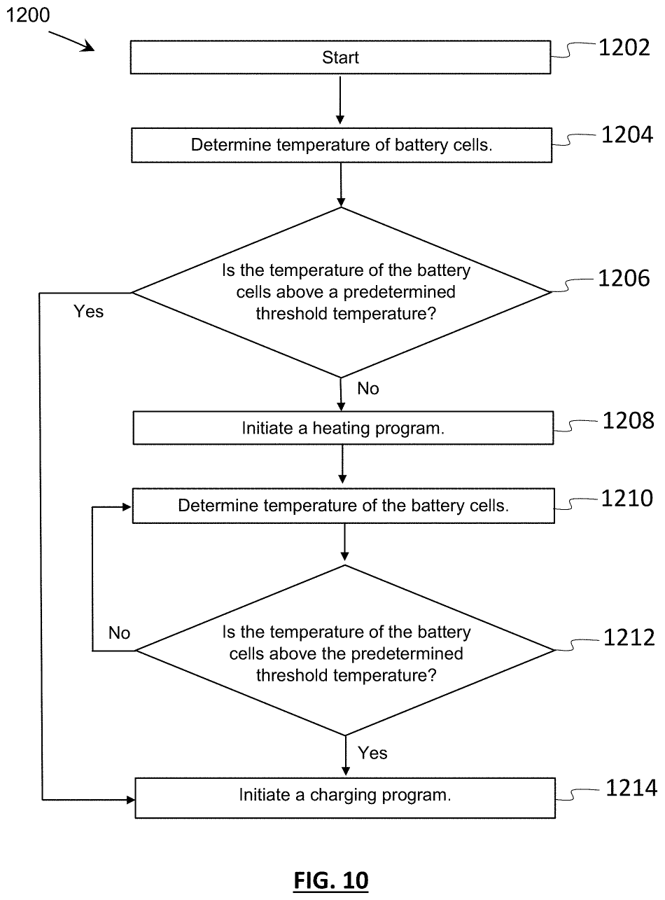

FIG. 10 is a flowchart illustrating a method 1200 for heating an interior of battery module 100 to increase the temperature of the associated lithium-ion battery cells 506 prior to recharging battery module assembly 100 with a power source (such as alternator 204 or charging source 220) when an estimated temperature of the battery cells 506 is below a temperature threshold. In some embodiments, an as described herein, the method 1200 can be performed by BMS 706. In some embodiments, the temperature threshold can be programmed to the BMS 706 to be a temperature between 0° C. and 10° C. The method can begin at block 1202. In some embodiments, the method 1200 can begin at block 1202 by BMS 706 detecting an incoming charge from a power source, indicating the start of a charging program by the power source. In some embodiments, the power source is alternator 204. In some embodiment, the power source is external charging source 220. In some embodiments, the method 1200 can start at block 1202 by BMS 706 sending an offset voltage to remote sense terminal 205 of alternator 204, as previously discussed. BMS 706 can start method 1200 in response to detecting that voltage or current levels of battery cells 506 are below a threshold value, and can perform method 1200 before, after, or simultaneous with sending offset voltage to remote sense terminal 205 to ensure battery cells 506 are at an appropriate temperature before being charged by alternator 204 responding to the offset voltage. Accordingly, in some embodiments, at block 1202 BMS 706 is configured to determine whether battery cells 706 need to be charged based on voltage or current values of battery cells 506 and send a signal to alternator 204 or charging source 220 that causes alternator 204/charging source 220 to send electrical power to battery module 100 for charging battery cells 506.

The method 1200 can continue at block 1204 by determining a temperature of battery cells 506 of module 100. BMS 706 uses temperature measurements from thermistors 812 proximal lithium-ion battery cells 506 that are continuously measured to determine a temperature of the battery cells 506. Alternatively, the temperature measurements may be measured intermittently. As previously discussed, thermally conductive material 726b connects each thermistor 812 to a corresponding battery cell 506, thus improving the temperature readings of the cells 506 and the model by which cell temperature is determined at block 1204. BMS 706 is configured to take the temperature readings from thermistors 812, taken in proximity to battery cells 506, and use the temperature readings in a calculation model to estimate the temperature of battery cells 506. The temperature of battery cells 506 determined by BMS 706 can be referred to as an estimated battery temperature since retrieving actual temperature readings from inside battery cells 506 would be impractical, and BMS 706 takes temperature readings using thermistors 812, which contact battery cells 506 via filler material 726b to estimate the temperature of battery cells 506. In calculating the estimated temperature of battery cells 506, BMS 706 may incorporate a temperature calculation model that considers a number of different factors related to the temperature of battery cells 506.

The method 1200 can continue at block 1206 by BMS 706 comparing the estimated temperature of the battery cells 506, estimated in block 1204, to a predetermined threshold temperature, and determining if the estimated temperature of the battery cells is above or below a predetermined threshold temperature. The predetermined threshold can be a threshold temperature that is programmed by a user depending on temperature and charging properties of battery cells 506. Battery cells 506 can be damaged when they are charged at freezing or near freezing temperatures. Accordingly, in some embodiments, the threshold temperature can be between 0° C. and 10° C. to ensure that the battery cells are not charged at freezing or below-freezing temperatures. However, the threshold temperature can be set at different temperatures depending on the chemistry properties of the particular cell 506 used. For example, in some embodiments, the threshold temperature can be set at between 0-20° C. Further, one with skill in the art will understand that BMS 706 can include a safety factor when comparing the estimated temperature of the battery cells 506 to the threshold to ensure that power is not supplied to the battery cells 506 while below the threshold temperature.

In response to determining, in block 1206, that the battery temperature is above the threshold temperature, the method 1200 can continue at block 1214 by initiating a battery cell 506 charging program. During charging program, BMS 706 can direct the incoming charge from the power source to battery cells 506 to charge battery cells 506. In some embodiments, the power source is alternator 204. In some embodiments, the power source is charging source 220. As previously discussed, battery cells 506 can become damaged when charging occurs at below freezing or near-freezing temperatures (0° C.-10° C.). Accordingly, when the battery temperature is determined to be above the protective threshold value, battery cells 506 can be charged without fear of damaging cells 506.

In response to determining, in block 1206, that the battery temperature is below or equal to the predetermined threshold temperature, the method 1200 can continue at block 1208 by initiating a heating program. During the heating program, BMS 706 can direct power from the power source to resistive heaters 810 to power the heaters 810 and to raise the internal temperature of the battery module 100 and the associated battery cells 506. In some embodiments, the power source is alternator 204. In some embodiments, the power source is charging source 220. In some embodiments, the power source is battery cells 506 and the BMS 706 directs power from battery cells 506 to heaters 810.

The method 1200 can continue at block 1210 by determining the temperature of the battery cells 506 during the heating program. The temperature of the battery cells 506 can be determined using the substantially the same techniques described in block 1204.

The method 1200 can continue at block 1212, by comparing the temperature of battery cells 506 during the heating program to the predetermined threshold temperature, and determining if the temperature of the battery cells taken during the heating program is above or below predetermined threshold temperature. The techniques for making the determination in block 1212 can be substantially the same as the techniques made to make the same determination in block 1206. In response to determining, at block 1212, that the temperature of battery cells 506 is above the predetermined threshold temperature, the method can continue at block 1214, where BMS 706 can initiate the charging program, as previously described above. The BMS 706 stops the heating program prior to initiating the charging program in block 1214. In response to determining, at block 1212, that the temperature of battery cells 506 is below or equal to the predetermined threshold temperature, the method can continue back to block 1210, where BMS 706 can continue to determine the temperature of the battery cells 506 during the heating program until the temperature of battery cells 506 is determined to be above the predetermined threshold value.

Although blocks 1202-1214 of method 1200 are described as occurring in a certain order, one with skill in the art will understand that blocks 1202-1214 can be performed according to various orders without departing from the scope of this disclosure. Further, one with skill in the art will understand that steps can be added or removed from method 1200 without departing from the scope of this disclosure.

One with skill in the art will understand that method 1200 can be used during a number of different times during operation or inaction of truck 220. For example, in some embodiments, method 1200 is employed during the charging of battery cells 506 in a cold environment. As previously discussed, battery cells 506 can be come damaged when charging of cells 506 is performed when the cells 506 are at a cold temperature. Accordingly, BMS 706 can perform method 1200 to ensure the cells 506 are at an appropriate temperature for charging before being charged by alternator 204 or external charging source 220.

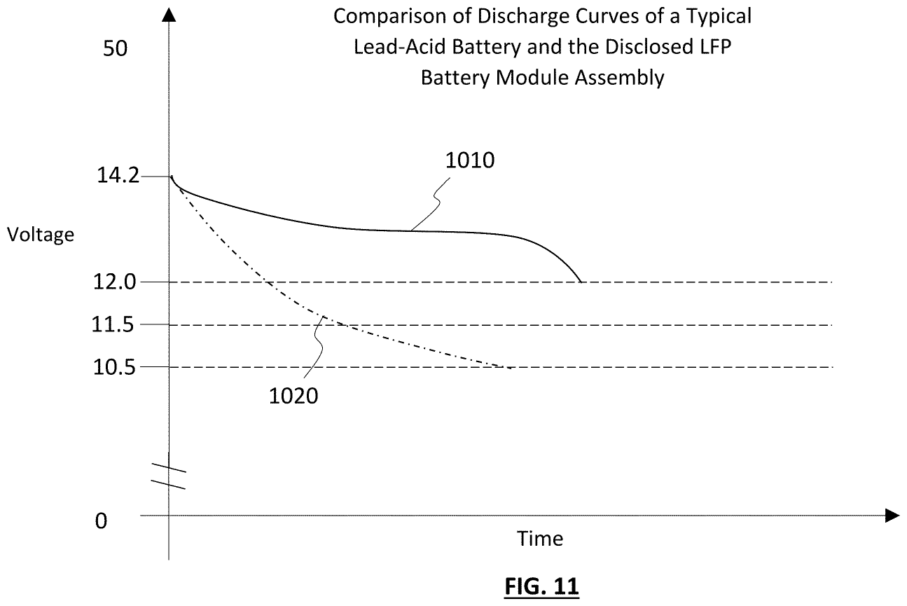

Referring now to FIG. 11, there is shown a graphical representation of a comparison of a constant discharge curve 1020 for a typical lead-acid battery (the dash-dot line) and an equal constant current discharge curve 1110 for the battery module assembly 100 herein disclosed (the solid line). It should be understood that, with a constant current load, the relative discharge time of each curve reflects the relative discharge time of each battery type.

Although both battery module assembly 100 and the typical lead-acid battery are shown at full charge being approximately 14.2 volts, there are stark differences plainly evident in the graph of each discharge curve. During operation of battery module assembly 100, there is shown a decrease in the voltage over time. However, the discharge curve 1010 of the battery module assembly 100 is relatively flat for the majority of the discharge cycle. Accordingly, during most of the discharge cycle, battery module assembly 100 maintains a higher voltage as compared to the typical lead-acid battery, due to its LFP chemistry. Furthermore, as shown in the graph, it is expected that the battery module assembly 100 is only discharged down to approximately 12 volts, as evidenced by the graph showing that the voltage of the battery module assembly 100 then drops to 12 volts at the end of the discharge cycle. Battery module assembly 100 can safely discharge up to 90% of its capacity in one discharge cycle.

In contrast, the lead-acid battery curve 1020 starts at a similar voltage, shown as 14.2 volts, and steadily decreases at a steady rate (i.e., there is no flat portion of the curve 1020) until it reaches 10.5 volts. Generally, the lead-acid battery typically should be discharged only to about 11.5 volts, and discharge 80% of its capacity. However, in order to increase the run-time of the lead-acid battery, some will discharge the lead-acid battery down to about 10.5 volts. Over-discharging in order to increase the present runtime of the lead-acid battery ultimately shortens the overall lifetime of the lead-acid battery.

Those skilled in the art will recognize that maintaining a higher voltage throughout most of the discharge cycle will increase the efficiency and reduce the performance variability in any loads, such as A/C compressors, heating elements, inverters, etc. Lead-acid batteries generally have a run-time of about 8 hours when new and 4-5 hours after multiple charge/discharge cycles. It is expected that battery module assembly 100 can achieve a run-time between 10 and 13 hours. This represents a significant benefit over the typical lead-acid batteries used in battery-powered APUs and other applications as herein described.

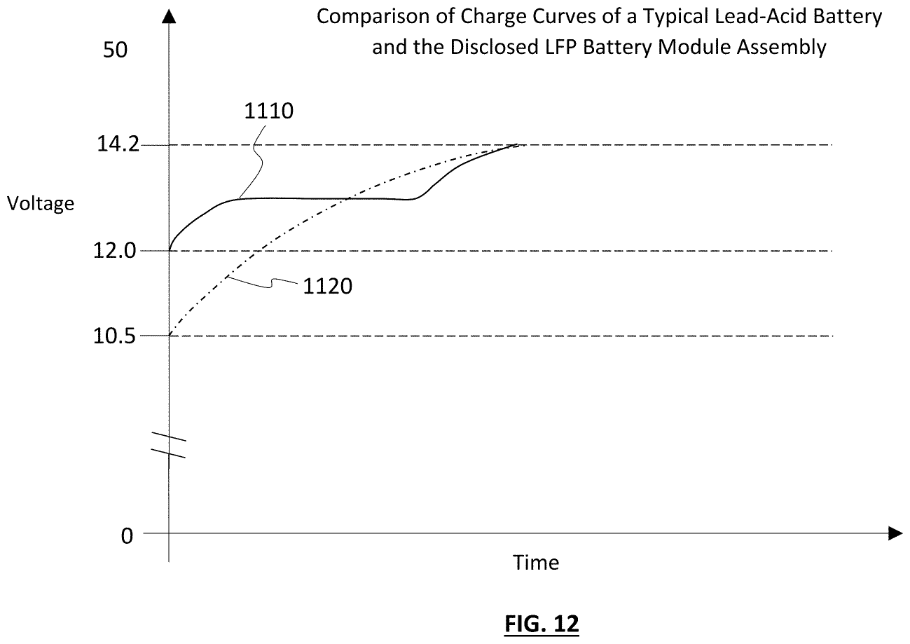

Turning now to FIG. 12, there is shown a graphical representation of the charge curve 1120 for a typical lead-acid battery (dash-dot line) as compared to a charge curve 1110 of battery module assembly 100. The curves 1120 and 1110 are charge curves corresponding to when both are charged at a constant voltage of 14.2 volts and are charged through the same cable resistance. Two obvious differences stand out immediately. First, the initial voltage for each is different. As stated above, it is contemplated that battery module assembly 100 will only be discharged down to about 12 volts. The charge curve for the typical lead-acid battery 1120 shows a lower initial voltage of 10.5 volts. This assumes that the lead-acid battery will be discharged to that voltage. However, even if the lead-acid battery is not over-discharged, one could expect the initial voltage of the lead-acid battery at the beginning of the charge cycle to be about 11.5 volts. Thus, when completely discharged, i.e., when charging is necessary, battery module assembly 100 starts the charge cycle at a higher voltage value.

A second difference between the two curves 1110 & 1120 is the shape of each curve. The lead-acid battery charge curve 1120 shows a substantially linear increase to the terminal voltage of 14.2 volts. In contrast, and similar to the discharge curve, the battery module assembly charge curve 1110 exhibits an initial increase, then the charge curve 1110 flattens for the majority of the charge cycle, until finally increasing again to reach the terminal voltage of 14.2 volts. Those skilled in the art will recognize that with constant voltage and constant charge resistance in the charging circuit, a flatter voltage curve with a lower average voltage will reflect a higher average charge current. It should also be recognized that, despite having about two times the capacity of the lead acid battery, due to the higher average charge current, battery assembly 100 charges in about the same amount of time as a lead-acid battery. Lastly, it should be recognized that a higher initial voltage will result in a lower initial charge current, which could reduce the peak power, and therefore size and cost, of the alternator required, even given the above improvements in total charge time.

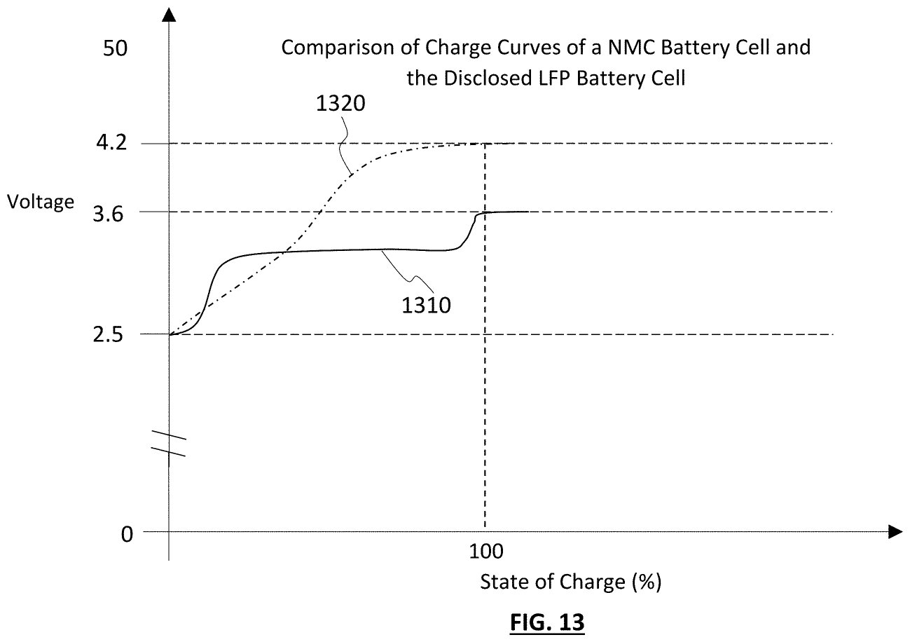

Turning now to FIG. 13, there is shown a graphical representation comparing, over time, the charge curve 1320 of a single lithium nickel manganese cobalt oxide (NMC) battery cell and the charge curve 1310 of the disclosed LFP battery cell 506 utilized in the battery module assembly 100. The charge curve of the NMC battery cell 1320 increases longer until it levels out at a higher voltage, shown here at 4.2 volts. In contrast, the LFP battery cell charge curve 1310 levels out sooner and remains at a constant voltage for longer. At the end of the charge cycle, LFP battery cell curve 1310 reaches 3.6 volts. When four cells 506 or cell banks 402 are in series, this represents the 14.2-14.4 volts of the fully charged battery module assembly 100, as seen in FIGS. 11 & 12.

As is evident from the graph of FIG. 13, the charge curve 1320 of an NMC battery cell exhibits a substantially steady increase to its terminal voltage. In contrast, as with the charge and discharge curves for the battery module assembly 100 seen in FIGS. 11 & 12, the charge curve 1310 of an individual LFP battery cell 506 initially increases relatively quickly to a flat portion of the curve. The charge curve 1310 remains relatively flat throughout most of the charge cycle.

The drawings and detailed descriptions herein should be considered illustrative and not exhaustive. They do not limit the invention to the particular forms and examples disclosed. To the contrary, the invention includes many further modifications, changes, rearrangements, substitutions, alternatives, design choices, and embodiments apparent to those of ordinary skill in the art, without departing from the spirit and scope of this invention.

Accordingly, in all respects, it should be understood that the drawings and detailed descriptions herein are to be regarded in an illustrative rather than a restrictive manner and are not intended to limit the invention to the particular forms and examples disclosed. In any case, all substantially equivalent systems, articles, and methods should be considered within the scope of the invention and, absent express indication otherwise, all structural or functional equivalents are anticipated to remain within the spirit and scope of the presently disclosed systems and methods.

What is claimed is:

1. An industrial vehicle comprising a rechargeable lithium-ion battery assembly configured to provide electric power to the industrial vehicle, wherein the industrial vehicle comprises:
an alternator electrically coupled with the rechargeable lithium-ion battery assembly and a primary battery of the industrial vehicle,
wherein the rechargeable lithium-ion battery assembly comprises:
an enclosure sized and shaped to operatively fit within a battery assembly housing of the industrial vehicle,
a positive terminal and a negative terminal disposed to be connected to wiring from an outside of the enclosure,
a plurality of battery cells disposed within the enclosure and interconnected with the positive and negative terminals to provide a combined electrical potential between the positive and negative terminals, where each battery cell of the plurality of battery cells is a lithium-ion battery cell, and
a printed circuit board assembly (PCBA) disposed in an orientation relative to a first array of battery cells of the plurality of battery cells within the enclosure such that a first end of each of the battery cells of the first array of battery cells is adjacent the PCBA, the PCBA comprising:
a collector plate electrically coupled with each battery cell of the first array of battery cells,
a temperature sensor configured to obtain temperature readings and disposed on a first surface of the collector plate facing the first array of battery cells,
a plurality of heaters configured to generate heat using electrical power and disposed on the first surface of the collector plate, and
an assembly processor configured to:
obtain temperature readings from the temperature sensor,
determine an estimated battery cell temperature of the plurality of battery cells based on the obtained temperature readings, and
in response to determining that the estimated battery cell temperature is less than a predetermined threshold temperature, initiate a heating program by delivering electrical power to the plurality of heaters from an electrical power source to enable the plurality of heaters to generate heat.

2. The industrial vehicle of claim 1, wherein, each of the plurality of heaters is disposed in contact with a thermally conductive material disposed between the collector plate and the first end of one of the battery cells of the first array of battery cells.

3. The industrial vehicle of claim 1, wherein the temperature sensor is disposed in contact with a thermally conductive material disposed between the collector plate and the first end of one of the battery cells of the first array of battery cells.

4. The industrial vehicle of claim 1 wherein there are a plurality of heaters associated with each of the battery cells of the first array of battery cells.

5. The industrial vehicle of claim 1, wherein there are a plurality of the temperature sensors disposed on the collector plate.

6. The industrial vehicle of claim 1, wherein the rechargeable lithium-ion battery assembly is configured to provide electric power to an auxiliary system of the industrial vehicle.

7. The industrial vehicle of claim 1, wherein the electrical power source is the alternator of the of the industrial vehicle.

8. The industrial vehicle of claim 1, wherein the assembly processor is further configured to initiate a charging program by delivering electrical power from the electrical power source to the plurality of batter cells for charging the plurality of battery cells in response to determining that the estimated battery cell temperature is greater than the predetermined threshold temperature.

9. The industrial vehicle of claim 1, wherein the rechargeable lithium-ion battery assembly further comprises a second PCBA disposed in an orientation relative to a second array of battery cells of the plurality of lithium-ion battery cells within the enclosure such that a first end of each of the battery cells of the second array of battery cells is adjacent the second PCBA, the second PCBA comprising:
a second collector plate electrically coupled with each battery cell of the second array of battery cells;
a second temperature sensor configured to obtain temperature readings and disposed on a first surface of the second collector plate facing the second array of battery cells; and
a second plurality of heaters configured to generate heat using electrical power and disposed on the first surface of the second collector plate,
wherein the second PCBA is electrically coupled with the PCBA such that the assembly processor is configured to obtain temperature readings from the second temperature sensor, deliver electrical power to the second plurality of heaters, and deliver power to the second array of battery cells.

10. A rechargeable lithium-ion battery assembly comprising:
an enclosure sized and shaped to operatively fit within a battery compartment of a vehicle;
a positive terminal and a negative terminal disposed to be connected to wiring from an outside of the enclosure;
a plurality of battery cells disposed within the enclosure and interconnected with the positive and negative terminals to provide a combined electrical potential between the positive and negative terminals, where each battery cell of the plurality of battery cells is a lithium-ion battery cell; and
a printed circuit board assembly (PCB) disposed in an orientation relative to a first array of battery cells of the plurality of battery cells within the enclosure such that a first end of each of the battery cells of the first array of battery cells is adjacent the PCBA, the PCBA comprising:
a collector plate electrically coupled with each battery cell of the first array of battery cells,
a temperature sensor configured to obtain temperature readings and disposed on a first surface of the collector plate facing the first array of battery cells,
a plurality of heaters configured to generate heat using electrical power and disposed on the first surface of the collector plate, and
an assembly processor configured to:
obtain temperature readings from the temperature sensor,
determine an estimated battery cell temperature of the plurality of lithium-ion battery cells based on the obtained temperature readings, and
in response to determining that the estimated battery cell temperature is less than a predetermined threshold temperature, initiate a heating program by delivering electrical power to the plurality of heaters from an electrical power source to enable the plurality of heaters to generate heat.

11. The rechargeable lithium-ion battery assembly of claim 10, wherein each of the plurality of heaters is disposed in contact with a thermally conductive material disposed between the collector plate and the first end of one of the battery cells of the first array of battery cells.

12. The rechargeable lithium-ion battery assembly of claim 10, wherein the temperature sensor is disposed in contact with a thermally conductive material disposed between the collector plate and the first end of one of the battery cells of the first array of battery cells.

13. The rechargeable lithium-ion battery assembly of claim 10 there are a plurality of heaters associated with each of the battery cells of the first array of battery cells.

14. The rechargeable lithium-ion battery assembly of claim 10, wherein there are a plurality of the temperature sensors disposed on the collector plate.

15. The rechargeable lithium-ion battery assembly of claim 10 wherein the electrical power source is the plurality of lithium-ion battery cells.

16. The rechargeable lithium-ion battery assembly of claim 10, wherein the electrical power source is an alternator of the vehicle.

17. The rechargeable lithium-ion battery assembly of claim 10, wherein the electrical power source is a battery assembly charger that is separate from the vehicle.

18. The rechargeable lithium-ion battery assembly of claim 10, wherein the assembly processor is further configured to initiate a charging program by delivering electrical power from the electrical power source to the plurality of battery cells for charging the plurality of battery cells in response to determining that the estimated battery cell temperature is greater than the predetermined threshold temperature.

19. The rechargeable lithium-ion battery assembly of claim 1 further comprising a second PCBA disposed in an orientation relative to a second array of battery cells of the plurality of lithium-ion battery cells within the enclosure such that a first end of each of the battery cells of the second array of battery cells is adjacent the second PCBA, the second PCBA comprising:
a second collector plate electrically coupled with each battery cell of the second array of battery cells;
a second temperature sensor configured to obtain temperature readings and disposed on a first surface of the collector plate facing the second array of battery cells; and
a second plurality of heaters configured to generate heat using electrical power and disposed on the first surface of the second collector plate,
wherein the second PCBA is electrically coupled with the PCBA such that the assembly processor is configured to obtain temperature readings from the second temperature sensor, deliver electrical power to the plurality of second heaters, and deliver power to the second array of battery cells.

20. A method of charging a plurality of lithium-ion battery cells of a battery assembly, the method comprising:
coupling a power source configured to charge the plurality of lithium-ion battery cells to the battery assembly;
calculating, using a processor of the battery assembly, an estimated temperature of the plurality of battery of cells using temperature readings from a temperature sensor of a printed circuit board assembly (PCBA) of the battery assembly adjacent to the plurality of lithium-ion battery cells;
comparing, using the processor, the estimated temperature of the plurality of battery cells to a threshold temperature value;
in response to determining that the estimated temperature of the plurality of battery cells is greater than the threshold temperature value, initiating a charging program, by the processor, to deliver electrical power from the power source to the plurality of lithium-ion battery cells for charging; and
in response to determining that the estimated temperature of the plurality of battery cells is less than the threshold temperature value:
initiating a heating program, by the processor, in which the processor delivers the electrical power from the power source to a plurality of heaters disposed on the PCBA to raise the temperature of the plurality of cells,
calculating during the heating program, by the processor, the estimated temperature of the plurality of the battery of cells using temperature readings from the temperature sensor, and
comparing, by the processor, the estimated temperature of the plurality of battery cells calculated during the heating program to the threshold temperature value,
in response to determining that the estimated temperature of the plurality of battery of cells calculated during the heating program is greater than predetermined threshold temperature value, ending the heating program and initiating the charging program, by the processor, to deliver the electrical power from the power source to the plurality of battery cells for charging.
